(19) United States
(12) Patent Application Publication
(10) Pub. No.: US 2007/0242428 A1
(43) Pub. Date: Oct. 18, 2007

(54) Structure for fixing fan with computer casing

(75) Inventor: Chun-Ju Lin, Taipei County (TW)

Correspondence Address: BACON & THOMAS, PLLC, 625 SLATERS LANE, FOURTH FLOOR, ALEXANDRIA, VA, 22314, US

(73) Assignee: ENERMAX TECHNOLOGY CORPORATION, Taoyuan County (TW)

(21) Appl. No.: 11/705,538

(22) Filed: Feb. 13, 2007

(30) Foreign Application Priority Data
Apr. 18, 2006 (TW) 095206507

(51) Int. Cl. H05K 7/20

(52) U.S. Cl. 361/692; 361/695

(57) ABSTRACT

The present invention discloses a structure for fixing a fan with a computer casing, and the structure includes a casing, an opening with a specific area on any side of the casing, and a locking hole proximate to each distal edge of the opening. The interval between two adjacent locking holes is equal to 170±5 mm, such that if a large fan is installed at the opening, a locking member can be secured directly to the corresponding locking hole, not only saving the time of drilling holes, but also resulting no increased area of the casing. The fan can be installed onto the casing for discharging any heat source produced by each component on a motherboard in the casing quickly, so that the heat will not remain in the casing, or drawing outside air into the casing to cool each component in the casing rapidly.

### BACKGROUND OF THE INVENTION

1. Field of the Invention

The present invention relates to a structure for fixing a fan with a computer casing, and more particularly to a structure having a casing, and the casing has an opening with an interval of 170±5 mm, so that a large fan can be installed directly onto the opening without the need of drilling a hole or increasing the area of the casing, so as to install the fan on a surface of the casing and lower the system heat source by dissipating heat out from a computer system.

2. Description of the Related Art

Computer has become one of the popular equipments in these days, but computer users and manufacturers are still facing the heat dissipation problem of the computer, particularly when a computer executes many application programs or drives too many peripherals, the computer system will be overheated, and such problem usually comes from a heat source of electronic components on a motherboard. As the performance and processing speed of a CPU are enhanced constantly, the heat dissipation issue becomes increasingly serious. Although the CPU or major component inside a computer already comes with a fan or heat sink, the fan or heat sink is disposed inside the computer, and the heat produced by CPU or components cannot be eliminated effectively. In addition to the heat source that is remained in the computer, noises are also produced. Therefore, the temperature cannot be lowered to a predetermined temperature for the expected system performance, and the execution speed of the computer will become very slow or the computer system may even crash.

Referring to FIG. 1 for a desktop computer system, the computer system has a casing, a fan hole at the back of the casing, and a fan installed in the casing and corresponding to the fan hole. The fan is combined with a power supply, so that the heat inside the casing can be eliminated by the fan. However, it is necessary to consider the way of eliminating or cooling down the heat source, since the fan and the power supply are combined with each other. Further, the area of the fan is very limited and cannot be aligned precisely at the position of the heat source, and thus the heat dissipation effect is very limited. If the number of fans installed in the casing is increased, then it is necessary to increase the area of the casing, which will make the layout of components in the casing very difficult.

### SUMMARY OF THE INVENTION

In view of shortcomings of the prior art, the inventor of the present invention based on years of experience in the medical measuring apparatus related industry to conduct extensive researches and experiments, and finally developed a structure for fixing a fan with a computer casing in accordance with the present invention to overcome the aforementioned shortcomings.

Therefore, it is a primary objection of the present invention to provide a structure for fixing a fan with a computer casing, and the structure is used in a device that eliminates a heat source produced in a computer, and the device has a casing for containing a motherboard, and the motherboard has a CPU and related electronic equipments or components, and the casing has an opening with a large area and disposed on a side facing the motherboard, and the periphery of the opening has a locking hole, and the linear interval between two adjacent locking holes is equal to 170±5 mm, so that the fan can be installed directly on the surface of the casing without increasing the area of the casing, and the large fan can be installed onto the opening, and the locking member can be passed through the fan base directly and secured with the corresponding locking hole without the need of drilling a hole, so as to make the installation simpler and easier. Such arrangement can eliminate the heat produced by components on the motherboard by the fan on the casing, and the heat can be discharged from the casing or cold air can be drawn from the outside into the casing by the large heat dissipating fan.

Another objective of the present invention is to provide a structure for fixing a fan with a computer casing, wherein the fan base can install a large fan or a plurality of small fans of different sizes.

A further objective of the present invention is to provide a structure for fixing a fan with a computer casing, wherein the fan installs a filter for filtering the dust in the air.

To make it easier for our examiner to understand the technical characteristics and effects of the present invention, we use preferred embodiments together with the attached drawings for the detailed description of the present invention.

### BRIEF DESCRIPTION OF THE DRAWINGS

FIG. 1 is a schematic perspective view of a prior art device;

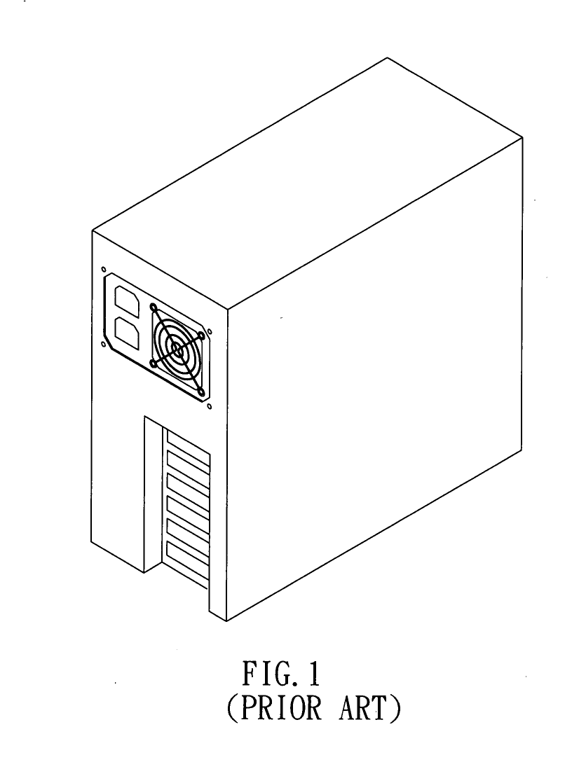

FIG. 2 is an exploded view of a first preferred embodiment of the invention;

FIG. 3 is a planar view of a first preferred embodiment of the invention;

FIG. 4 is a perspective view of a first preferred embodiment of the invention;

FIG. 5 is a perspective view of a second preferred embodiment of the invention;

FIG. 6 is a perspective view of a third preferred embodiment of the invention; and

FIG. 7 is a perspective view of an application of the invention.

### DETAILED DESCRIPTION OF THE PREFERRED EMBODIMENTS

In describing a preferred embodiment of medical measuring apparatus in accordance with the invention illustrated in the drawings, specific terminologies and numerals will be resorted to for the sake of clarity. However, the invention is not intended to be limited to the specific terms and numerals so selected, and it is to be understood that each specific term includes all technical equivalents which operate in a similar manner to accomplish a similar purpose.

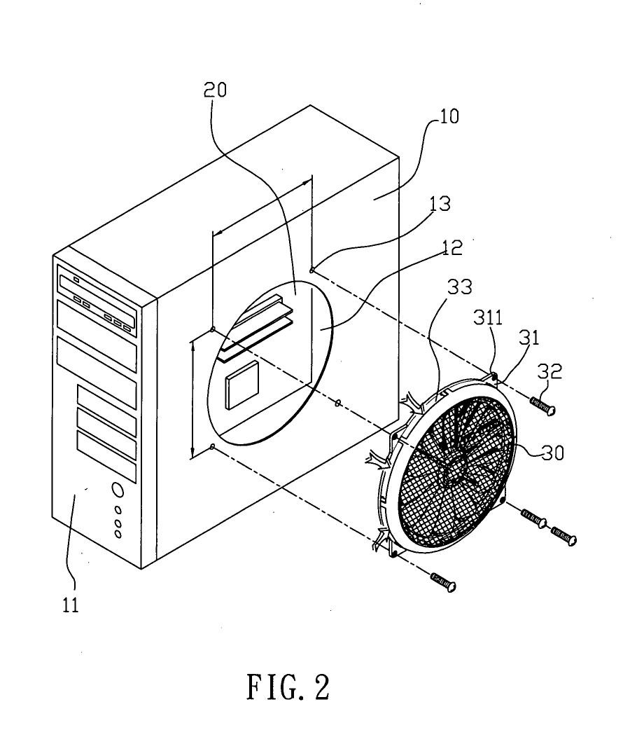

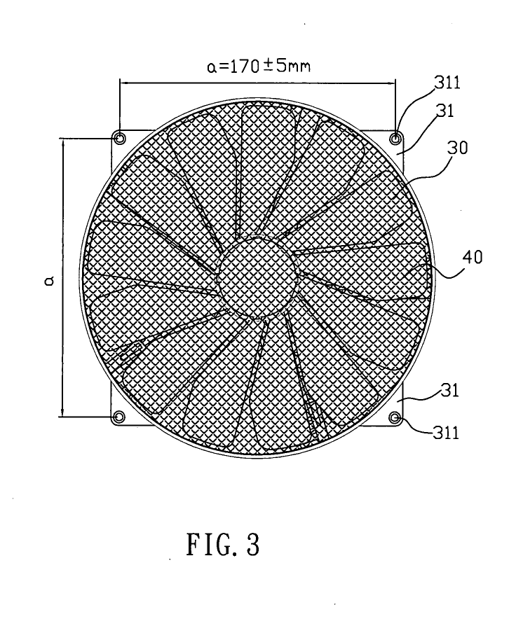

Referring to FIGS. 2 to 6 for a structure for fixing a fan with a computer casing in accordance with the present invention, the device has a casing 10, and the casing of this embodiment is a tower desktop computer, and the front side of the casing 10 has a front panel 11, and the casing 10 contains a motherboard 20, and the motherboard 20 installs electronic components such as a CPU and an interface card, etc. The casing 10 also has an opening 12 disposed on a corresponding side facing the motherboard 20 and with a size equal to half of the motherboard 20, and the casing 10 has a locking hole 13 disposed at each distal edge of the opening 12, and the linear distance between two adjacent locking holes 13 is equal to 170±5 mm, and the opening 12 installs a heat dissipating fan 30 which is a large fan in this embodiment, and the periphery of the fan 30 has a protruding ear 31 protruded outward, and the protruding ears 31 separately have a plurality of locking holes 311, and the locking holes 311 correspond to the locking holes 13 at the periphery of the opening 12, such that the locking member 32 (which is a screw rod in this embodiment) can be passed through the locking hole 311 and secured into the locking hole 13, and fixed onto the casing 10. Such arrangement not only successfully installs the fan 30 onto a surface of the casing 10, but also results in no increase of area of the casing 10. Since the interval of the locking holes 13 complies with the locking holes 311 of the fan 30, it is not necessary to drill holes for the installation. During its use, the heat produced by all electronic components on the motherboard 20 can be discharged by the fan 30. The invention definitely can eliminate the heat in the casing 10 by discharging the heat out from the casing 10 or drawing cold air from the outside into the casing 10.

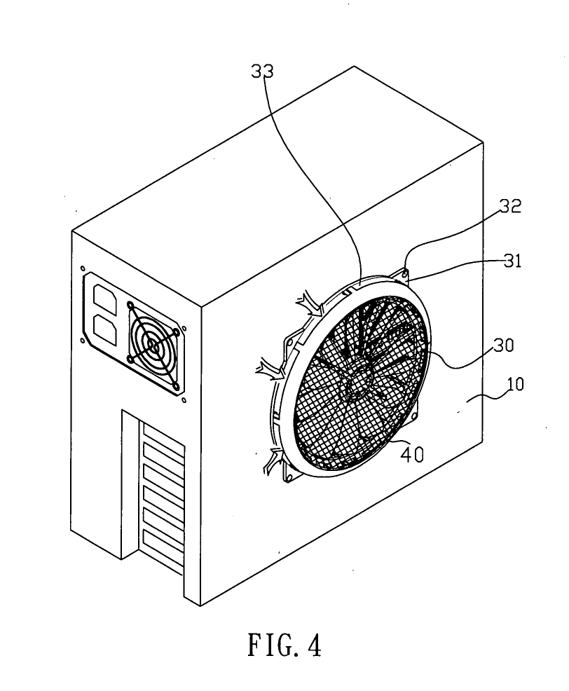

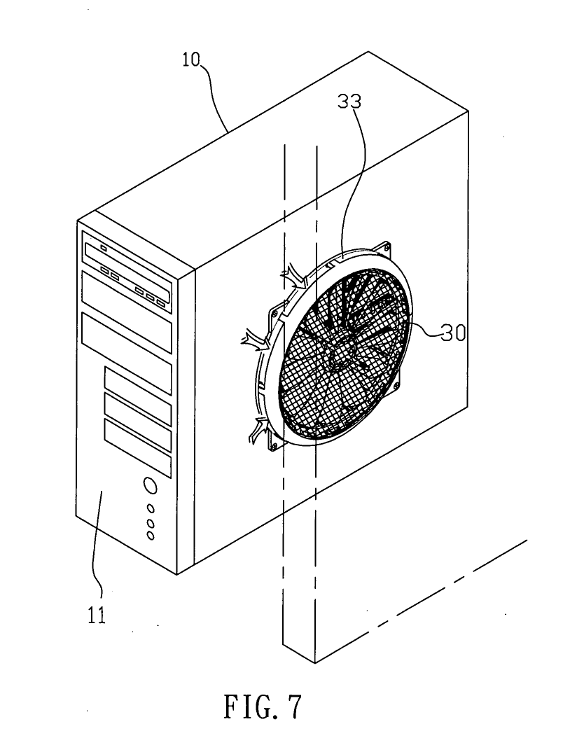

In FIGS. 4 to 7, the surrounding of the fan 30 has through holes 33, such that if the casing 10 is attached to a wall or a table leg, then the flow of the outside air or discharged air will not be blocked, but air can be entered into or discharged from the through holes 33 (as shown in FIG. 7).

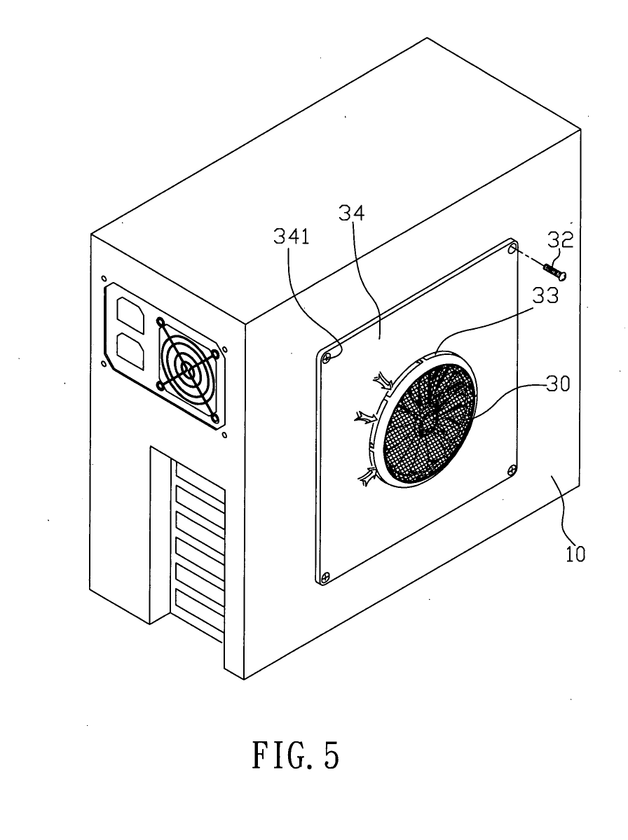

Referring to FIG. 5, the fan 30 can be fixed to a fan base 34, and the fan base 34 can be integrated or locked with the fan 30, and each distal edge of the fan base 34 has a locking hole 341 corresponding to a locking hole 13 (not shown in the figure) with an equal distance apart, such that a locking member 32 (which is a screw rod) can be passed through the locking hole 341 and secured into the locking hole 13 and fixed onto the casing 10. Such arrangement not only successfully installs the fan 30 onto a surface of the casing 10, but also needs not to increase the area of the casing 10. Since the interval of the locking holes 13 complies with the locking holes 311 of the fan 30, therefore it is not necessary to drill any hole for the installation.

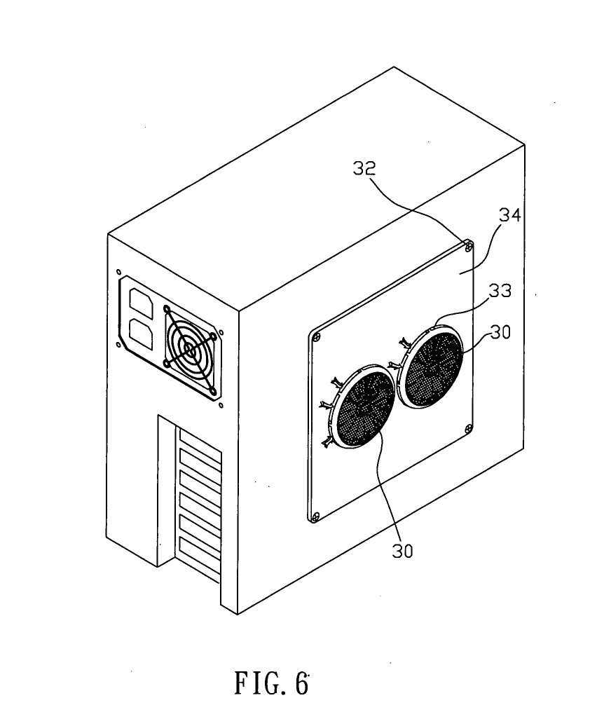

Referring to FIG. 6, the fan base 34 can install a plurality of small fans 30 with different sizes, and this embodiment adopts two small fans.

Referring to FIGS. 4 to 6, the heat dissipating fan 30 of the invention can install a filter 40 for filtering dusts or ashes in the air.

In summation of the description above, the design of the present invention can enhance the heat dissipating efficiency of the computer and its special effect can overcome the shortcomings of the prior art. The structural and technical characteristics of the invention are disclosed in the foregoing embodiments, and the invention complies with the requirements of patent applications, and is duly submitted to file a patent application.

While the invention has been described by means of specific embodiments, numerous modifications and variations could be made thereto by those skilled in the art without departing from the scope and spirit of the invention set forth in the claims.

What is claimed is:

1. A structure for fixing a fan with a computer casing, applied in a computer or an electron device, and said structure comprising:
a casing, having an opening disposed on said casing and at a corresponding side of a motherboard, and at least one locking hole disposed at a position proximate to the periphery of said opening, and a linear interval between said two adjacent locking holes is equal to 170±5 mm; and
a fan, installed at said opening of said casing.

2. The structure for fixing a fan with a computer casing of claim 1, wherein said fan has a locking hole disposed at a periphery of said fan and corresponding to said locking hole of said opening, and a liner interval of said two adjacent locking hole of said fan is equal to 170±5 mm.

3. The structure for fixing a fan with a computer casing of claim 1, wherein said opening has an area greater than half of said motherboard.

4. The structure for fixing a fan with a computer casing of claim 1, wherein said fan is coupled to a fan base, and said fan base has a locking hole corresponding to said locking hole at the periphery of said opening, and a linear interval of said through holes is equal to 170±5 mm.

5. The structure for fixing a fan with a computer casing of claim 4, wherein said fan base installs a large fan.

6. The structure for fixing a fan with a computer casing of claim 4, wherein said fan base installs at least one small fan.

7. The structure for fixing a fan with a computer casing of claim 1, wherein said fan installs a filter.

8. The structure for fixing a fan with a computer casing of claim 1, wherein said fan has a through hole at the periphery of said fan for preventing a block of air flow.
